(19) United States
(12) Patent Application Publication
(10) Pub. No.: US 2022/0190464 A1
(43) Pub. Date: Jun. 16, 2022

(54) Component Carrier Having at Least a Part Formed as a Three-Dimensionally Printed Structure Forming an Antenna

(71) Applicant: AT&S Austria Technologie & Systemtechnik Aktiengesellschaft, Leoben (AT)

(72) Inventors: Marco Gavagnin, Leoben (AT); Markus Leitgeb, Trofaiach (AT); Ahmad Bader Alothman Alterkawi, Graz (AT); Ferdinand Lutschounig, Ferlach (AT); Heinz Moitzi, Zeltweg (AT); Thomas Krivec, Zeltweg (AT); Gernot Grober, Graz (AT); Erich Schlaffer, St. Lorenzen (AT); Mike Morianz, Graz (AT); Rainer Frauwallner, Tragöss (AT); Hubert Haidinger, Sankt Margerethen an der Raab (AT); Gernot Schulz, Graz (AT); Gernot Gmunder, Parschlug (AT)

(21) Appl. No.: 17/653,628

(22) Filed: Mar. 4, 2022

Related U.S. Application Data
(63) Continuation-in-part of application No. 16/153,565, filed on Oct. 5, 2018.

(30) Foreign Application Priority Data
Oct. 6, 2017 (DE) 102017123307.5

(51) Int. Cl. H01Q 1/22; H05K 1/02; B33Y 80/00; B33Y 10/00; H01Q 9/04

(52) U.S. Cl. CPC H01Q 1/2283; H05K 1/0284; H05K 1/0203; H05K 2201/10098; B33Y 10/00; H01Q 9/0407; H01Q 9/0485; B33Y 80/00

(57) ABSTRACT

A component carrier and a method for manufacturing a component carrier are disclosed. The component carrier comprises a carrier body having a plurality of electrically conductive layer structures and/or electrically isolating layer structures and a three-dimensionally printed structure forming at least a part of an antenna on the carrier body.

### CROSS-REFERENCE TO RELATED APPLICATIONS

The present application is a continuation-in-part application based on and claims priority to co-pending U.S. patent application Ser. No. 16/153,565, filed on Oct. 5, 2018, which application claimed priority to German Patent Application No. 102017123307.5, filed Oct. 6, 2017, the disclosures of which applications are hereby incorporated herein by reference.

### TECHNICAL FIELD

Embodiments of the invention relate to a component carrier, wherein at least a part of the component carrier is formed as a three-dimensional structure forming at least part of an antenna. Furthermore, other embodiments relate to a method for manufacturing a component carrier, wherein at least a part of the component carrier is formed as a three-dimensional structure which forms an antenna.

Technological Background

Conventional component carriers are manufactured as single-layered or multi-layered component carriers. Usually, they are manufactured photochemically by laminating the electrically conducting layers by a photoresist. After the illumination of the photoresist through a mask (or reticle) which includes the desired structure of the electrically conductive layer, either the illuminated or the non-illuminated portions of the photoresist are removed in a corresponding solution. Important for the quality and the functionality of the component carrier are, on the one hand, the materials used and, on the other hand, the deposition (or application) and/or connection of the used materials among each other. Due to the ever-increasing requirements relating to the component carriers due to the increasing miniaturization in electrical engineering, also the requirements relating to the materials used and the structure of the very component carrier are increasing. For this reason, there may still be room for improved component carriers and their manufacturing methods.

### SUMMARY

There may be a need to provide a component carrier comprising an antenna structure, which can be manufactured easily and which allows more flexibility in the arrangement of the component carrier structures.

Exemplary embodiments of the present invention are described as the subject matters having the features according to the independent claims. Further example embodiments are described in the dependent claims.

According to a first exemplary embodiment of the invention, there is provided a component carrier comprising a carrier body having a plurality of electrically conductive layer structures and/or electrically isolating layer structures; and a three-dimensionally printed structure forming at least a part of an antenna on the carrier body. The antenna can partly or completely be formed by the three-dimensionally printed structure. The antenna can comprise the three-dimensionally printed structure, or the three-dimensional printed structure can comprise the antenna.

According to a further exemplary embodiment of the invention, there is provided a method for manufacturing a component carrier, the method comprising connecting a plurality of electrically conductive layer structures and/or electrically isolating layer structures for forming a carrier body; and forming an antenna at least partially as a three-dimensionally printed structure on the carrier body by three-dimensional printing.

According to a further exemplary embodiment of the invention, there is provided a method of designing a component carrier, the component carrier comprising a carrier body having a plurality of electrically conductive layer structures and/or electrically isolating layer structures; and a three-dimensionally printed structure forming at least a part of an antenna on the carrier body. The method comprises determining at least one parameter, which used in a step of three-dimensional printing the three-dimensionally printed structure, so as to obtain a predetermined resonant frequency of the antenna, wherein the parameter is at least one of a height, an area, and a volume of the antenna. By three-dimensional printing the antenna, the bandwidth of the resulting antenna can be tuned, and manufacturing tolerances can be compensated for. For example, the smaller the height is, the higher the resonant frequency is. As another parameter, the resonant frequency can be tuned by the dielectric constant Dk.

### Overview of Embodiments

Present solutions of conductor board antennas may have either micro-stripe antennas, which may be fabricated during a standard manufacturing process for conductor boards, or external antennas, which may be manufactured as a surface-mounted (SMT) antenna, or may be attached with separate connectors. In order to possibly bring together the advantages of both variants and in order to possibly reduce the manufacturing costs, a three-dimensionally printed antenna can be used. Thereby, an antenna having better antenna characteristics and a higher freedom of design may be manufacturable, which may be depositable (or attachable) directly on the component carrier and/or the conductor board. This three-dimensionally printed antenna can be used in radar, IoT (Internet of Things), or global positioning satellite system (GPS) applications.

According to an exemplary embodiment, the antenna structure may be formed, such that the antenna structure may be printable directly on and/or in the carrier body. In particular, the antenna structure can be printed in/on at least one of the plurality of layer structures.

The term “component carrier” may be understood in particular to refer to each supporting structure, which may be capable to receive thereon and/or therein one or more components for providing a mechanical support and/or electrical connection. In other words, a component carrier can be configured as a mechanical and/or an electrical carrier for components. In particular, a component carrier can be one of a conductor board, an organic interposer and an IC (integrated circuit) substrate. A component carrier can also be a hybrid board, which may combine the different types of component carriers mentioned above.

According to an embodiment of the invention, the component carrier may have a carrier body having a stack of at least one electrically isolating layer structure and at least one electrically conducting layer structure. For example, the component carrier can be a lamination from the mentioned electrically isolating layer structure(s) and the electrically conducting layer structure(s), which lamination may be formed in particular by an application of mechanical pressure, if desired supported by thermal energy. The mentioned stack can provide a board-shaped (or plate-shaped) component carrier, which may be capable to provide a large mounting surface for further components and which may be nevertheless very thin and compact. The term “layer structure” may be understood to refer in particular to a continuous layer, a structured layer or a plurality of non-consecutive islands within a common plane. The component carrier may have a carrier body, which may consist of different layer structures, i.e., of electrically isolating and electrically conducting layer structures. The different layer structures can be arranged such that the sequence of the electrically isolating layer structure and the electrically conducting layer structure changes (or alternates). For example, the carrier body may have a layer structure, which may begin with the electrically conducting layer structure, which may be followed by an electrically isolating layer structure, and which may be further followed by an electrically conducting layer structure, such that the stack of the component carrier may be formed.

The term “at least a part” of the component carrier may be understood to refer in particular to at least one layer of the component carrier, electrically conducting components of the component carrier, or any other parts, which may form the component carrier. The at least one part can be a conducting part of the component carrier and/or a non-conducting and/or isolating part of the component carrier, and/or also a combination thereof. Furthermore, the at least one part can be formed on and/or in at least one of the electrically conducting layer structures and/or the electrically isolating layer structures. In particular, the complete component carrier can also be formed as a three-dimensionally printed structure.

The term “three-dimensionally printed structure” may be understood to refer in particular to a structure, which may be manufactured by a three-dimensional printing process. During a three-dimensional printing process, the 3D printed structures may be constructed layer by layer. In particular, a three-dimensional printing may be understood to refer to a printing using powdery material, a 3D printing with using meltable material, a 3D printing by fluidic materials. A process, which may use printable material in powdery form is the Selective Laser Sintering (SLS) or also the Selective Laser Melting (SLM). A further process, which may use printable materials in powder form, is electron beam melting (EBM), or also electron beam additive manufacturing (EBAM). A 3D printing with meltable materials can be understood to refer in particular to a Fused Filament Fabrication (FFF), or to a Fused Deposition Modelling (FDM, melting layering). Melted materials, which can be used for this process, can be in particular acrylonitrile-butadiene-styrene (ABS) or polylactic acid (PLA). 3D printing with fluidic materials can be understood to refer in particular to a manufacturing process, which may work on the basis of UV-sensitive plastic materials (such as photo-polymers, or also other light-sensitive materials, which may react differently to different wavelengths). In particular, the 3D printing with fluidic materials can include the so-called stereo-lithography (SLA). During the 3D printing process, the three-dimensionally printed structure may be constructed layer by layer.

The forming of a part of a component carrier using a three-dimensional printing process can simplify the manufacturing of the component carrier. Furthermore, the design of the one part of the component carrier can be adapted in a simple manner to its function and/or to a position on the component carrier, such that the design of the very component carrier may be adaptable easily. The using of the 3D printing can guarantee more precision during the formation of the one part of the component carrier. Furthermore, an arrangement of different parts on the component carrier by the 3D printing method can be implemented with a high precision.

It is noted that the term “layer structures” can, in the framework of the present document, be used representatively for the plurality of the electrically conducting layer structures and the electrically isolating layer structures.

In an embodiment, the antenna is one of a dielectric-resonant antenna formed of a dielectric material, preferably having a dielectric constant in a range between 5 and 20, more preferred between 8 and 12; and a patch antenna formed of a conductive material, preferably having a dielectric constant in a range between 2 and 6, more preferred between 2 and 4.

In an embodiment, the antenna is formed of two different materials which are different in terms of their dielectric constants, wherein the different materials are comprised either in a single material layer or separately in different layers or areas.

In an embodiment, the antenna comprises, in a cross section or in a plan view, different areas having different dielectric constants.

In an embodiment, the antenna is formed of copper, silver, ceramics or plastics.

In an embodiment, the antenna comprises a core which is coated or over-molded, wherein a coating or over-molding material is different to the material of the core.

In an embodiment, the antenna comprises a two-dimensional or three-dimensional matrix of at least one active antenna element and at least one switchable antenna element, wherein the three-dimensionally printed structure is a three-dimensionally printed connection structure which connects the at least one active antenna element with the at least one switchable antenna element.

In an embodiment, the antenna is formed in a cavity.

In an embodiment, the three-dimensionally printed structure comprises a filter structure, a waveguide structure, or a resonating structure, or a combination thereof.

In an embodiment, the antenna is directly formed on a semiconductor chip.

In an embodiment, the antenna comprises a hollow structure.

In an embodiment, the antenna comprises sidewalls which are tapered with respect to a main surface of the component carrier by an angle which is smaller than 90 deg., in particular smaller than 80 deg.

In an embodiment, the three-dimensionally printed structure is formed according any one of the following embodiments: the three-dimensionally printed structure is formed in the interior and/or at a surface of the carrier body; the three-dimensionally printed structure is formed along a stacking direction of the plurality of layer structures, the three-dimensionally printed structure is formed perpendicular to a stacking direction of the plurality of layer structures; the three-dimensionally printed structure has different cross-sectional areas in a stacking direction of the plurality of layer structures and/or perpendicular to a stacking direction of the plurality of layer structures; the three-dimensionally printed structure forms at least partially the electrically conductive layer structures and/or the electrically isolating layer structures; the three-dimensionally printed structure is formed as a rigid and/or flexible structure; the three-dimensionally printed structure is formed at least partially as an electrically conducting connection element which is a terminal pad, a pin, a female connector, a micro-pin, an, in particular annular, sliding contact, and/or a spring contact; the three-dimensionally printed structure is formed as a damping element; the three-dimensionally printed structure is formed as a mechanical connection element which is a threaded bush, a snap-action connection, a hook and loop connection, a slide fastener connection, a guiding rail, and/or a guiding pin; the three-dimensionally printed structure is a heat conducting structure; the three-dimensionally printed structure has at least one material component, which is copper, aluminum, steel, titanium, metal alloy, plastic material, or a photoresist; the three-dimensionally printed structure is formed as a reinforcement structure of the electrically conductive layer structures and/or of the electrically isolating layer structures; the three-dimensionally printed structure forms a surface of the carrier body, wherein areas of the surface differ in respect of their hardness, roughness and/or elasticity; the three-dimensionally printed structure is formed as an active or passive electronic component, a resistor, a capacitor, an inductor, an electrical contact, a breaking cut-out, an USB contact, and/or a QFN contact; the three-dimensionally printed structure is formed as a sensor, an actuator, a magnetic sensor, EMC shielding, and/or a micro-electromechanical system, the three-dimensionally printed structure is formed as at least one element, which is an optical element, a light detector, a light emitter, a lens, a micro-lens, or a waveguide; the three-dimensionally printed structure is formed as at least one element, which is a microphone, a loudspeaker or a Helmholtz horn.

In an embodiment, the component carrier has a surrounding component carrier region and a surrounded component carrier region, which is surrounded by the surrounding component carrier region, wherein at least a part of the surrounding component carrier region and/or of the surrounded component carrier region is formable as a further three-dimensionally printed structure.

In an embodiment, the component carrier is formed according any one of the following embodiments: the carrier body has a recess, wherein the three-dimensionally printed structure is printed within the recess; at least a part of the carrier body is encapsulated by the three-dimensionally printed structure as an encapsulation, wherein the encapsulation comprises at least one of steel, titanium, silver, aluminum or gold; the component carrier further has: an electronic component, surface-mounted at and/or embedded in at least one of the plurality of the electrically conductive layer structures and/or of the electrically isolating layer structures; the three-dimensionally printed structure is formed such that a further three-dimensionally printed structure is printable thereon; a further part of the component carrier is formed as a further three-dimensionally printed structure, wherein the three-dimensionally printed structure and the further three-dimensionally printed structure consist of different materials; at least one of the plurality of electrically conductive layer structures has at least one of copper, aluminum, nickel, silver, gold, palladium and wolfram, wherein one of the mentioned materials is optionally coated with graphene; at least one of the plurality of electrically isolating layer structures has at least one of a resin, reinforced or non-reinforced resin, epoxy resin, bismaleimide-triazine resin, FR-4, FR-5, cyanate ester, polyphenylene derivatives, glass, prepreg material, polyimide, polyamide, liquid crystalline polymer, epoxy-based composition film, polytetrafluoroethylene, a ceramic, and a metal oxide; the component carrier is formed as a board; the component carrier is configured as one of a conductor board and a substrate; the component carrier is configured as a lamination-type component carrier.

In an embodiment, a soldering depot is depositable on the conducting connection element; wherein the mechanical connection element is configured to form a releasable connection; wherein at least a region of the three-dimensionally printed structure is formed of steel and/or titanium; wherein the three-dimensionally printed structure forms at least a part of a component.

In an embodiment, the electronic component is an electrically non-conductive and/or electrically conductive inlay, a heat transmission unit, a directed lighting element, an energy generation unit, an active electronic component, a passive electronic component, an electronic chip, a data storage device, a filter device, an integrated circuit, a signal processing component, a power management component, an optoelectronic converter, a voltage converter, a cryptographic component, a transmission and/or receiving unit, an electromechanical converter, an actuator, a micro-electromechanical system, a micro-processor, a capacitance, a resistance, an inductance, an accumulator, a switch, a camera, a magnetic element, a further component carrier, or a logic chip; wherein the three-dimensionally printed structure has a higher heat conductivity and/or current conductivity than the further three-dimensionally printed structure; wherein the three-dimensionally printed structure and/or the further three-dimensionally printed structure are formed of aluminum; wherein the three-dimensionally printed structure and the further three-dimensionally printed structure are formed on top of each other for forming a bi-metal element.

In an embodiment, the antenna comprises a two-dimensional or three-dimensional matrix of at least one active antenna element and at least one switchable antenna element, and the method comprises connecting the at least one active antenna element to the at least one switchable antenna element by three-dimensionally printing the three-dimensionally printed structure as a three-dimensionally printed connection structure.

In an embodiment, the step of three-dimensional printing comprises at least one of selective laser melting, selective laser sintering, aerosol jet printing for smooth surface, electron beam melting, and inkjet-printing.

In an embodiment, the three-dimensional printing further comprises introducing a printable material in a manufacturing device, melting the printable material in the manufacturing device, and supplying the melted printable material on and/or in the carrier body for forming at least one layer of at least a part of the three-dimensionally printed structure; depositing a printable material on and/or in the carrier body, and solidifying the deposited printable material for forming at least one layer of at least a part of the three-dimensionally printed structure.

In an embodiment, through the method at least one of the following embodiments is implemented: the three-dimensionally printed structure is formed by at least one of selective laser melting, selective laser sintering, and electron beam melting; prior to the solidifying of the printable material, the printable material is melted by a thermal treatment device; the printable material is deposited by a material supply jet nozzle; the carrier body is provided in a material bed, before the printable material is supplied to the carrier body.

In an embodiment, the method further comprising at least one of: moving the material supply jet nozzle for forming a further layer of the at least a part of the three-dimensionally printed structure; and moving the carrier body for forming a further layer of the at least a part of the three-dimensionally printed structure.

In an embodiment, the method further comprising arranging the carrier body in a container, providing a solidifiable fluid material in the container, solidifying the fluid material by a treatment device on and/or in the carrier body for forming at least one layer of at least a part of the three-dimensionally printed structure.

In an embodiment, the method further comprising moving the carrier body for forming a further layer of the at least a part of the three-dimensionally printed structure.

In an embodiment, the method comprising forming a cavity having a complementary shape to the antenna; and filling the cavity by the three-dimensionally printed structure to form the antenna.

In an embodiment, the antenna comprises a two-dimensional or three-dimensional matrix of at least one active antenna element and at least one switchable antenna element; wherein the three-dimensionally printed structure is designed to connect the at least one active antenna element to the at least one switchable antenna element by three-dimensionally printing the three-dimensionally printed structure as a three-dimensionally printed connection structure.

According to an exemplary embodiment, the at least one electrically conducting layer structure may have at least one of copper, aluminium, nickel, silver, gold, palladium, and wolfram. Even though copper may be generally preferred, also other materials or coated versions thereof may be possible, which may in particular be coated with supra-conducting material, such as graphene.

According to an exemplary embodiment of the invention, at least one of the plurality of the electrically isolating layer structures may have at least one of resin (such as reinforced or non-reinforced resins, in particular epoxide resin or bismaleimide-triazine resin, further in particular FR-4 or FR-5), cyanate ester, polyphenylene derivatives, glass (in particular glass fibres, multi-layer glass, glass-like (or translucent) materials), prepreg material, polyimide, polyamide, liquid-crystalline polymer (LCP), epoxide-based construction film, polytetrafluoroethylene, a ceramics, and a metal oxide. Reinforced materials, such as fabrics (meshes), fibres or spheres, for example fabricated from glass (multi-layer glass) can also be used. Although prepreg or FR4 may generally be preferred, also other materials may be possible. For high-frequency applications, high-frequency materials, such as polytetrafluoroethylene, liquid-crystalline polymer and/or cyanate ester resins, can be implemented in the component carrier as an electrically isolating layer structure.

According to an embodiment of the invention, the component carrier may be formed as a board (or plate, or disk). This may contribute to a compact design, wherein the component carrier nevertheless may provide a large basis for attachment of components. Furthermore, in particular, a naked chip as an example for an embedded electronic component, can be embedded in a thin board, such as a conductor board, in a conventional manner due to the low thickness.

According to an embodiment of the invention, the component carrier may be configured as one of a conductor board and a substrate (in particular, an IC substrate).

The term “conductor board” (PCB) may be understood to refer in particular to a component carrier (which is plate-shaped (i.e., planar), three-dimensionally bent (for example, if it is manufactured using 3D printing) or which may have any other shape), which may be formed by laminating plural electrically conductive layer structures with plural electrically isolating layer structures, for example by application of pressure, if this is desired accompanied by the supply of thermal energy. The electrically conducting layer structures may be of copper as a preferred material for the PCB technology, wherein the electrically isolating layer structures may comprise a resin and/or glass fibres, a so-called prepreg or FR4 material. The different electrically conducting layer structures can be connected with each other in any desired manner by the forming of through-holes through the lamination, for example by laser drilling or mechanical drilling, or by filling this with electrically conducting material (in particular copper), in order to thereby possibly form vias as through-hole connections. Apart from one or plural components, which can be embedded in a conductor board, a conductor board may generally be configured for receiving one or more components on one or opposite surfaces of the board-shaped conductor board. These can be connected to the respective main surface by soldering. A dielectric part of a conductor board can consist of resin with reinforcement fibres (such as glass fibres).

The term “substrate” may be understood herein to refer in particular to a small component carrier, which may have substantially the same size as a component attached thereon (in particular an electronic component). Especially, a substrate can be understood as a carrier for electronic connections or electric networks, likewise as a component carrier comparable with a conductor board (e.g., a PCB), however with a significantly higher density of laterally and/or vertically arranged connections. Lateral connections may be, for example, conducting paths, wherein vertical connections can be, for example, drill holes. These lateral and/or vertical connections may be arranged within the substrate and can be used, in order to possibly provide electrical and/or mechanical connections of incorporated components or non-incorporated components (such as exposed chips), in particular of IC chips, with a conductor board or intermediate conductor boards arranged therebetween. Thus, the term “substrate” may comprise also “IC substrates”. A dielectric part of a substrate can be made of resin with reinforced spheres (such as glass spheres).

In an embodiment, the component carrier may be a lamination-type component carrier. In such an embodiment, the component carrier may be a composition of plural layer structures, which may be stacked and may be connected with each other by application of a pressure force and which may be accompanied by heat, if desired.

In the following, further exemplary embodiments of the method for manufacturing a component carrier are described.

In an exemplary embodiment of the method, the three-dimensional printing may have an introducing of printable material into a processing device. Furthermore, the method may have a melting of the printable material in the processing device, and a supplying of the melted printable material on and/or in the carrier body for forming at least one layer of at least a part of the three-dimensionally printed structure. According to this embodiment, meltable material may be used for the 3D printing. The material can be introduced in a 3D printer. The 3D printer can have a printing head, which may function as a processing device. The pressure head can be a heatable extruder, in which the material may be supplied. The material may be melted within the extruder, such that the material can be transferred through the extruder (for example through an extruder nozzle) to a structure, on which the melted material is to be applied and/or introduced (such as, e.g., on at least one of the layer structures). The processing device and the carrier body can be moved relatively to each other. After the introduced/applied layer of the part of the carrier body may be solidified (or cured), subsequently, a further layer of the part of the carrier body may be formed by the extruder. The number of the formed layers of the one part of the carrier body may be depending on the size, in particular on the height, of the one part of the carrier body. For example, a formed layer may have a thickness (and/or height) of 50 μm. The part of the carrier body can have a thickness (and/or height) of 200 μm. Therefore, four layers may be printed on top of each other, in order to possibly form the part of the carrier body. For example, the processing device can have a high resolution, such that individual layers may have a thickness of approximately 1 μm to 16 μm. Furthermore, more than one processing device can be used during the manufacturing process, in order to possibly simultaneously apply different materials, and/or in order to possibly form different layers of different parts of the carrier body. According to this embodiment, it can be possible to print simultaneously more than one part of the carrier body. Two parts of the same carrier body can be formed in and/or on different planes of the carrier body or on different layer structures. The used melted material can consist of an electrically conducting material, such as copper, or it can be enriched with electrically conductive material components.

According to a further embodiment of the method, the three-dimensional printing may have an applying of a printable material, in particular a powdery material, on and/or in the carrier body, and a solidifying and/or consolidating of the applied printable material for forming at least one layer of at least a part of the three-dimensionally printed structure. The term “solidifying/consolidating” can refer in particular to a step or an activity, in which the printable material may be brought in a solid state, wherein the solid state may be one state of the at least one layer of the at least one part of the three-dimensional structure. For example, the solidifying/consolidating can be at least one of the following: attaching, adhering, hardening, tempering, solidifying, melting and hardening, or hardening of the printable material. The forming of the at least one layer of the part of the carrier body can be performed by applying an adhesive on the at least one layer of the part of the carrier body. The adhesive may glue the individual particles of the powdery material together, such that a corresponding layer may be formed. The adhesive agent can be applied by a printing head on the powder layer. The adhesive agent (or also binding agent) can be a fluidic adhesive agent. During the 3D printing with powder, the first (lowermost) layer may be applied with the aid of a fluidic adhesive agent on the powder layer. The 3D printer may draw a 3D image of the first layer of the powder bed and may glue the material particles of the powder together. After this step, a further thin powder layer may be applied on the first layer, and the 3D printing procedure may be repeated for generating a second layer. Thus, a 3D model of the one part of the component carrier may be a generated layer by layer by the gluing together of powder layers. The 3D structure may grow from the bottom to the top in this case. For this purpose, the powder bed may be lowered by the height of a powder layer. The powder and the adhesive agent can may consist of different materials. For example, of plastic powder, ceramics powder, glass powder or other metallic powdery materials. Also, it may be possible to use metal as a powdery material, for example copper powder, for 3D printing of conducting parts of the component carrier. The 3D printer can be equipped with at least one printing head or also with plural printing heads. The used adhesive agent can be a conducting adhesive agent, such that layer structures may be formed by conducting metal powder and conducting adhesive agent, in order to possibly be electrically conducting. The adhesive agent can be cured (or hardened) by a thermal treatment, such as a heat lamp or a laser.

According to a further exemplary embodiment of the method, the three-dimensionally printed structure may be formed by at least one of selective laser melting, selective laser sintering, and electron beam melting.

According to a further exemplary embodiment of the method, prior to the solidifying/consolidating of the printable material, the printable material may be melted by a thermal treatment device, in particular a laser device. Instead of using an adhesive agent, which may glue the material particles with each other, the individual layers can be melted together and namely by a thermal treatment device, such as a laser. This thermal treatment method may be called selective laser sintering (SLS) or selective laser melting (SLM). By the thermal treatment of the materials, metals, ceramics or sand can be used. If SLS or SLM is used as a manufacturing method, the forming of the layer from the powdery material may be performed by a laser, wherein the laser may melt or sinter the powder material, in order to possibly form at least one layer of the one part of the component carrier. In the case of using an SLS or SLM method, a use of an adhesive agent for connecting the powdery material may be obsolete.

Furthermore, the printable material can be melted by a controllable electron beam, which may be referred to as the so-called electron beam melting (EBM). This manufacturing processing may allow the use of materials having a higher melting point, such as the melting of titanium materials.

According to a further exemplary embodiment of the method, the printable material may be applied by a material supply jet nozzle. The printable material, e.g., powder, may be provided by the material supply jet nozzle, such that the printable material to be applied may be sprayed out of the material supply jet nozzle. By the material supply jet nozzle, a precise amount of material can be provided, such that only the part of the component carrier to be printed may have to be covered with a (new) layer of the printable material, instead of the whole component carrier.

According to a further exemplary embodiment, the method may further include moving the material supply jet nozzle for forming a further layer of the at least a part of the three-dimensionally printed structure. The term “moving” can be understood in particular to refer to a movement along at least one spatial direction. Furthermore, an adjusting of the material supply jet nozzle in relation to the carrier body can be understood from this. For example, a distance between the carrier body and the material supply jet nozzle can be adjusted. Furthermore, the material supply jet nozzle can be moved along further spatial directions, in order to adjust a desired alignment between the carrier body and the material supply jet nozzle. As a function of the movement of the material supply jet nozzle, the thickness and the location of the layer to be formed can be adjusted. This step can be repeated so long, until a final thickness of the part of the three-dimensionally printed structure is achieved. Thus, the one part of the three-dimensionally printed structure may be formed layer by layer by spraying on printable material.

According to a further exemplary embodiment, the carrier body may be provided in a material bed, before the printable material is supplied to the carrier body. The carrier body can be placed in the material bed. The component carrier can be covered completely by the printable material, if the component carrier is arranged in the material bed. Furthermore, the carrier body can be arranged in the material bed such that a surface of the carrier body, on which the one part of the three-dimensionally printed structure may be formed, may be arranged with a defined distance to a surface of the material bed. Therefore, a desired thickness of the printable material can be applied between the environment and the surface of the carrier body. Thereafter, the applied printable material may be solidified (or cured) between the surface of the material bed and the carrier body. The solidification and/or consolidation can be performed by a treatment device, which may be configured for applying thermal energy on the surface of the material bed and/or for radiating a pre-defined wavelength of the light for a photo-polymerization of the surface of the material bed.

According to a further exemplary embodiment, the method may further include a moving of the carrier body for forming a further layer of the at least one part of the three-dimensionally printed structure. After the printing of a layer of the one part of the three-dimensionally printed structure on/in the carrier body, the carrier body can be moved. In particular, the carrier body can be lowered by the thickness of the next layer to be printed of the one of the three-dimensionally printed structure.

According to a further exemplary embodiment, the method may further include the arranging of the carrier body in a container. Furthermore, the three-dimensional printing may have a providing of a solidifiable fluid material in the container, and a solidifying (or curing) of the fluid material by a treatment device, in particular a laser device, on and/or in the carrier body for forming at least one layer of at least a part of the three-dimensionally printed structure. In particular, the fluid material may be solidified after the arranging of the carrier body. An ultraviolet (UV) laser can be used for solidifying. The laser may be focused on the container, which may contain the fluid material. The laser can be used in order to solidify desired regions of the fluid material, in order to possibly form a defined design of the one part of the three-dimensionally printed structure. The fluid material can be solidified, in particular hardened, and may form an individual layer of the desired one part of the three-dimensionally printed structures. These steps can be repeated for each layer to be printed of the one part. In order to move the carrier body or the surface, on which the one part shall be 3D printed, a lift platform can be used. The lift platform can be moved by a distance, which may correspond to a thickness of an individual layer of the structure to be printed in the container. After the solidifying, an abrading device and/or a knife can be moved over the solidified layer and can scrape off material, in order to possibly provide a homogeneous distribution of the fluid material for the next layer to be 3D printed. Thereafter, the laser may solidify further desired regions of the fluid material for forming the desired design of the one part of the three-dimensionally printed structure. These steps can be repeated until the desired 3D structure is achieved. After the forming of the complete structure of the one part of the three-dimensionally printed structure, the component carrier can be finishingly solidified in an oven (ultraviolet oven). This manufacturing process can also be performed with mixed materials, such as ceramic and photopolymer mixtures. Furthermore, more than one laser can be used during the process.

According to a further exemplary embodiment, the fluid material may be a photo-sensitive material, in particular a fluid material, which may be photo-sensitive under ultraviolet light of the laser. As a further manufacturing process, which may use fluid materials, the so-called multi-jet modelling, or poly-jet modelling can be applied. In these methods, the fluid material may be solidified by a light source directly during the application.

According to a further exemplary embodiment, the method may further have a moving of the carrier body for forming a further layer of the at least a part of the three-dimensionally printed structure.

It is noted that the embodiments described herein represent only a limited selection of possible embodiment variants of the invention. Thus, it is possible to combine the features of individual embodiments with each other in a suitable manner, such that for the skilled person a plurality of different embodiments is to be considered as being obviously disclosed with the embodiment variants explicit herein. In particular, some embodiments of the invention are described by device claims, and other embodiments of the invention are described by method claims. The skilled person, upon reading this application, will however understand clearly that unless it is explicitly indicated differently, in addition to a combination of features, which belong to one type of the subject of the invention, also an arbitrary combination of features, which belong to different types of subjects of the invention, is possible.

### BRIEF DESCRIPTION OF THE DRAWINGS

FIG. 1 shows a component carrier according to an exemplary embodiment of the invention.

FIG. 2 shows a component carrier having an encapsulation according to an exemplary embodiment of the invention.

FIG. 3 shows a component carrier having a surrounding component carrier region and a surrounded component carrier region according to an exemplary embodiment of the invention.

FIG. 4 shows a component carrier having connection elements according to an exemplary embodiment of the invention.

FIG. 5 shows a connection element at a component carrier according to an exemplary embodiment of the invention.

FIG. 6 shows a sliding contact at a component carrier according to an exemplary embodiment of the invention.

FIG. 7 shows a cross-section through a sliding contact at a component carrier according to an exemplary embodiment of the invention.

FIG. 8 shows a further cross-section through a sliding contact at a component carrier according to an exemplary embodiment of the invention.

FIG. 9 shows a component carrier having an encapsulation according to an exemplary embodiment of the invention.

FIG. 10 shows another view of the component carrier having the encapsulation according to an exemplary embodiment of the invention.

FIG. 11 shows a component carrier having aluminium layers according to an exemplary embodiment of the invention.

FIG. 12 shows a component carrier having 3D printed in aluminium layers according to an exemplary embodiment of the invention.

FIG. 13 shows another view of the component carrier having 3D printed in aluminium layers according to an exemplary embodiment of the invention.

FIG. 14 shows a component carrier having damping elements according to an exemplary embodiment of the invention.

FIG. 15 shows a component carrier having connection elements according to an exemplary embodiment of the invention.

FIG. 16 shows a component carrier having a reinforcement structure and/or a heat-conducting structure according to an exemplary embodiment of the invention.

FIG. 17 shows a three-dimensional printing method according to an exemplary embodiment of the invention.

FIG. 18 shows a component carrier having different three-dimensionally printed structures according to an exemplary embodiment of the invention.

FIG. 19 shows a component carrier having 3D printed glass fibres according to an exemplary embodiment of the invention.

FIG. 20 shows a component carrier having a threaded bush according to an exemplary embodiment of the invention.

FIG. 21 shows a component carrier having a threaded bush and a fixing element according to an exemplary embodiment of the invention.

FIG. 22 shows a component carrier having a three-dimensionally printed structure and a further three-dimensionally printed structure according to an exemplary embodiment of the invention.

FIG. 23 shows a component carrier having an optical element according to an exemplary embodiment of the invention.

FIG. 24 shows a component carrier having a bridge according to an exemplary embodiment of the invention.

FIG. 25 shows a component carrier having a bridge according to a further exemplary embodiment of the invention.

FIG. 26 shows a component carrier having a waveguide according to an exemplary embodiment of the invention.

FIG. 27 shows a component carrier having a three-dimensionally printed structure formed as at least a part of a component.

FIG. 28 shows a schematic cross-sectional view of a component carrier.

FIG. 29 shows a schematic perspective view of a component carrier.

FIG. 30 shows a schematic cross-sectional view of a component carrier.

FIG. 31 shows a schematic perspective view of a component carrier.

FIG. 32 shows a schematic cross-sectional view of a component carrier.

FIG. 33 shows a schematic cross-sectional view of a component carrier.

FIG. 34 shows a schematic plan view of a component carrier.

FIG. 35 shows a schematic cross-sectional view of a component carrier.

FIG. 36 shows a schematic plan view of a component carrier.

FIG. 37 shows a schematic plan view of a component carrier.

FIG. 38 shows a schematic cross-sectional view of a component carrier.

FIG. 39 shows a schematic plan view of a component carrier.

FIG. 40 shows a schematic cross-sectional view of a component carrier.

FIG. 41 shows a schematic plan view of a component carrier.

FIG. 42 shows a schematic cross-sectional view of a component carrier.

FIG. 43 shows a schematic cross-sectional view of a component carrier.

FIG. 44 shows a schematic cross-sectional view of a component carrier.

FIG. 45 shows a schematic cross-sectional view of a component carrier.

### DETAILED DESCRIPTION OF ILLUSTRATED EMBODIMENTS

In the following, embodiment examples are described with reference to the appended drawings for a further explanation and a better understanding of the present inventions. The present inventions can be realized by embodiments which are different to those of the drawings. In particular, details like via connections between the layers or structured traces can be embodied in a different manner.

The illustrations in the drawings are schematically presented. In different drawings, similar or identical elements are provided with the same reference signs.

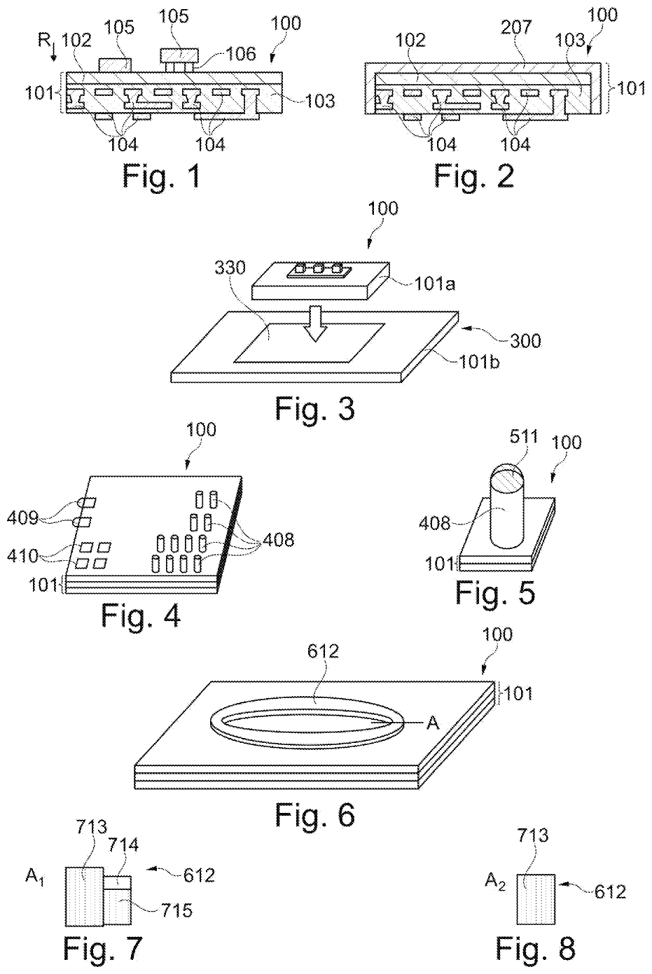

In the following and with reference to FIG. 1, a component carrier 100 is described, wherein the component carrier 100 may have a carrier body 101. The carrier body 101 may have a plurality of electrically conductive layer structures 104 and/or electrically isolating layer structures 103. At least a part of the component carrier 100 may be formed as a three-dimensionally printed structure. Thus, the three-dimensionally printed structure can form at least partially the electrically conductive layer structures 104 and/or the electrically isolating layer structures 103. The three-dimensionally printed structure can be formed in the interior and/or at a surface of the carrier body 101. In FIG. 1, the three-dimensionally printed structure can be embodied as an electrically conducting layer structure 104 on the surface of the carrier body 101. Furthermore, the three-dimensionally printed structure can be the electrically conducting layer structure 104 in the interior of the electrically isolating layer structures 103. The three-dimensionally printed structure may be formed along a stacking direction R of the plurality of layer structures. As can be recognized in FIG. 1, the inner electrically conducting layer structures 104 may be formed on an electrically isolating layer structure 103. Furthermore, a lowermost layer may be formed again of a layer of electrically conducting layer structures 104, such that the carrier body 101 may consist of stacked layer structures 103, 104. Furthermore, the three-dimensionally printed structure can be formed perpendicular to a stacking direction R of the plurality of layer structures. If the three-dimensionally printed structure is the electrically conducting layer structure 104, then may extend in FIG. 1 at the same time along a stacking direction R and perpendicular to the stacking direction R of the plurality of layer structures 103, 104. As can be recognized in FIG. 1, the three-dimensionally printed structure as the electrically conducting layer structure 104 may have different cross-sectional areas, in particular in a stacking direction R of the plurality of layer structures and/or perpendicular to a stacking direction R of the plurality of layer structures. The electrically conductive layer structure (as a 3D printed structure) may further have tapering cross-sections along a stacking direction.

The component carrier 100 may further have at least one component 105, in particular an electronic component 105, which may be surface-mounted on and/or embedded in at least one of the plurality of electrically conductive layer structures 104 and/or the electrically isolating layer structures 103. The component 105 may be arranged directly on the carrier body 101 or may be fixed on the carrier body 101 by connection elements 106. In FIG. 1, the components 105 may be arranged on the carrier body 101.

In the following and with reference to FIG. 2, a component carrier 100 is illustrated, wherein at least a part of the carrier body 101 may be at least partially encapsulated by the three-dimensionally printed structure as an encapsulation 207. The carrier body 101 may have at least one side, which may be free from the encapsulation 207. At the side, which is free from the encapsulation 207, electrically conducting layer structures 104 may be arranged. These electrically conducting layer structures 104 may be free from the encapsulation in order to possibly establish electrical contacts to corresponding other components. The encapsulation 207 may have a U-shape. Other shapes of the encapsulation 207 may also be possible, such as an oval or a rounded shape. The encapsulation 207 may be adapted accordingly to the shape of the component carrier 100. Furthermore, the encapsulation can have different cross-sections both along a stacking direction and also perpendicular to a stacking direction, in order to possibly cope with different requirements. If the encapsulation is to be protected from outer influences, such as from strong loads, then a thicker cross-section may be used than for an encapsulation 207 for light loads (or wears). The encapsulation 207 can be a steel and/or a titanium encapsulation.

According to FIG. 2, at least one of the plurality of layer structures 103, 104 can be formed as three-dimensionally printed structure, wherein a further three-dimensionally printed structure may be printable thereon. In FIG. 2, the encapsulation 207 may be printed as a further three-dimensionally printed structure on the three-dimensionally printed structure of the copper layer 102 and/or at least one of the plurality of layer structures 103, 104.

In the following and with reference to FIG. 3, a component carrier 100 is illustrated, which may have a surrounding component carrier region 101b and a surrounded component carrier region 101a, which may be surrounded by the surrounding component carrier region 101b, wherein in particular at least a part of the surrounding component carrier region 101b and/or of the surrounded component carrier region 101a may be formable as a further three-dimensionally printed structure. In other words, the component carrier 100 can have two regions of carrier bodies 101a, 101b, wherein a first region of the carrier body 101a may be an inner region and a second region of the carrier body 101b may be an outer region, which may surround the inner region of the carrier body 101a. The second region of the carrier body 101b (or the surrounding component carrier region 101b) may have a recess 330, within which the first region of the carrier body 101a may be formed. In particular, the first region of the carrier body 101a may be printed three-dimensionally within the recess 330. On the other hand, it may also be possible that the component carrier 100 may be printed three-dimensionally in a recess 330 of a further component carrier 300. In this case, thus, two different component carriers 100, 300 may be present, which can be manufactured by 3D printing methods.

In the following and with reference to FIG. 4, a component carrier 100 is illustrated, in which the three-dimensionally printed structure may be formed at least partially as an electrically conducting connection element 408, 409, 410, in particular as a terminal pad 410, a contact 409, a pin 408, a female connector, a micro-pin 408. A plurality of pins 408 may be arranged on the carrier body 101, which pins 408 may represent electrical contacts for components 105. Furthermore, terminal pads 410 and/or solder pads may be arranged on the carrier body, on which pads components 105 can be fixed directly and/or on which pins or other electrical conductors can be fixed, in order to possibly connect the carrier body 101 to further electrical elements (such as for example electrical components or electrical devices).

In the following and with reference to FIG. 5, a component carrier 100 is illustrated, on the carrier body 101 of which a pin 408 may have been printed three-dimensionally, wherein a solder depot 511 may have been printed on the pin 408 as a further three-dimensionally printed structure. The pin 408 can thus be provided at the same time with a corresponding solder depot 511. Also, other electrical contacts, such as for example contacts or solder pads as shown in FIG. 4, can be printed thereon with a solder depot 511.

In the following and with reference to FIG. 6, the three-dimensionally printed structure may be formed at least partially as an electrically conducting connection element, as a, in particular annular, sliding contact 612. The sliding contact 612 may establish electrical connections between moved parts, whereby for example a current collector may slide over a metal surface and may tap the electrical energy. By the use of a 3D printed material for the sliding contact 612, materials, in particular metals and/or metal alloys, can be used, which may be resistant against chemical, mechanical, and thermal loads. As a function of which layer thickness is selected for the sliding contact 612, the latter may be less susceptible to a mechanical wear at a high layer thickness than sliding contacts having a low layer thickness. Sliding contacts 612 having a high layer thickness therefore also may have a longer lifetime.

In the following and with reference to FIG. 7, a cross-section of a sliding contact 612 is illustrated. The sliding contact 612 may consist of a material combination of three different materials, i.e., material A 713, material B 714 and material C 715. Material A 713 may represent a stable metal alloy against wear of friction and may be formed as a carrier ring for the sliding contact 612. Material B 714 may be gold, which may be applied galvanically on material C 715 or may be printed by 3D printing on material C 715. Hereby, material B 714 may serve as a tap for the electrical signal, wherein gold may have a good electrical conductance value, whereby the signal transmission may be improved. Material C 715 may be a carrier metal for the gold material, material C 715 can for example be copper. In a sliding contact 612 having such a construction, the mechanical load may rest primarily on material A 714, such that a low pressure (and a low wear of friction) may act on material B 714, such that material B 714 may have a longer lifetime. Other materials and/or other metal alloys can also be used.

In the following and with reference to FIG. 8, a cross-section of a sliding contact 612 is illustrated. This sliding contact 612 may have a high layer thickness, whereby the layer thickness of the sliding contact 612 can be adjusted effectively and directly by the three-dimensional printing.

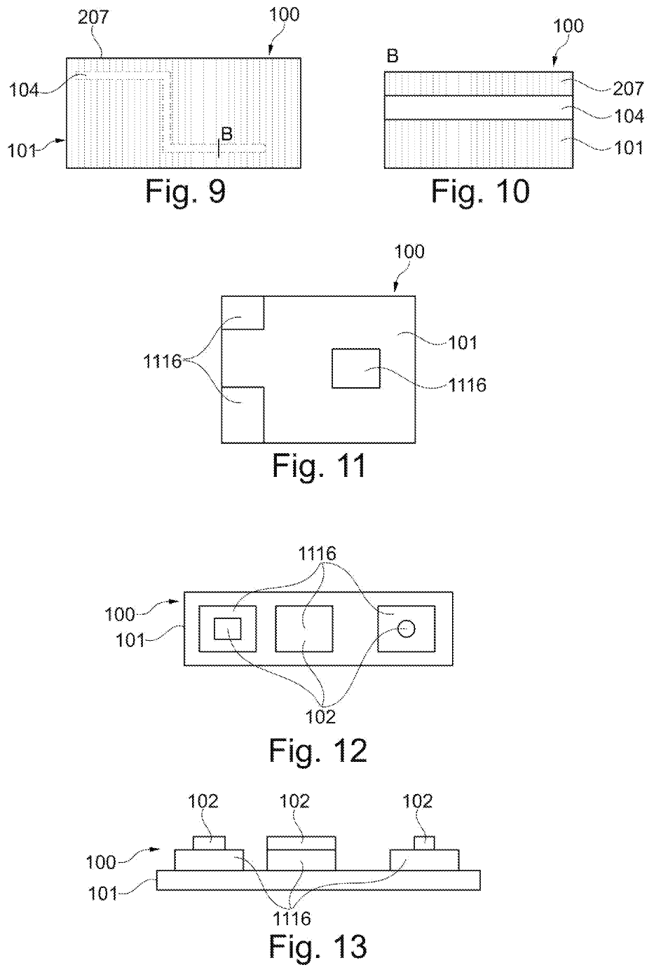

In the following and with reference to FIG. 9, a component carrier 100 is illustrated, which may have an encapsulation 207. An electrically conducting layer 104, which may be formed as a conductive path, may be arranged in the carrier body 104 of the component carrier 100. The encapsulation 207 may surround at least one side of the component carrier 100, and may further consist of steel or titanium. As a function of the application range, other materials can be used for the encapsulation 207. If the encapsulation 207 serves as a surface protection of the carrier body 101, for example a hard material, such as steel, may be of advantage.

In the following and with reference to FIG. 10, a component carrier 100 which may have a three-dimensional structure as an encapsulation 207 is illustrated in another view. A cross-section B through the component carrier 100 of FIG. 9 is shown. The encapsulation 207 may be formed on a surface of the carrier body 101, such that the encapsulation 207 can serve as a surface protection. The electrically conducting structure 104, which may be protected from outer influences by the encapsulation 207, may be arranged under the encapsulation. The carrier body 101 can consist of a multi-layer conductor board or also of a single layer conductor board. The three-dimensionally printed structure thus may form a surface of the carrier body, wherein regions of the surface can differ in respect of their hardness, roughness and/or elasticity. As a function of which material is used in the three-dimensional structure (encapsulation 207), it can have different properties. Thus, for example, an encapsulation 207 made of titanium may be harder and thus more resistant against mechanical influences than an encapsulation 207 made of steel. A corresponding roughened surface of the three-dimensional structure (the encapsulation 207) can guarantee a higher heat dissipation than a smooth surface.

If for example a plastic material is used for the encapsulation 207, this can serve a flexible conductor board as a surface protection, and can simultaneously guarantee the flexibility of the flexible conductor board. In particular, one and the same surface can have different regions, which may have for example different roughnesses. Thereby, a region of the surface of the three-dimensional structure (encapsulation 207), which may be arranged over an electrically conducting layer structure 104, can have a higher roughness than surrounding regions of the surface of the three-dimensional structure (the encapsulation 207), in order to possibly dissipate produced heat from the electrically conducting layer structure 104 by a high roughness. Furthermore, the surface of the three-dimensionally printed structure (the encapsulation 207) can have another material over the electrically conducting layer structure, in order to possibly protect the structures lying thereunder better from outer mechanical influences. For example, at least a region of the three-dimensionally printed structure can be formed of steel and/or titanium.

In the following and with reference to FIG. 11, a component carrier 100 is illustrated, which may have aluminium layers 1116 on at least a part of the carrier body 101. In particular, in FIG. 11, three regions of the carrier body 101 may be covered by aluminium layers 1116. The aluminium layer 1116 may be printed directly on the carrier body 101. The different aluminium layers 1116 can have different layer thicknesses, such that each aluminium layer 1116 may have another thickness. The aluminium layer 1116 can be applied at each position on/in the carrier body 101.

In the following and with reference to FIG. 12, a component carrier 100 which may have three aluminium layers 1116 is illustrated, wherein the aluminium layers may be each covered with a copper layer 102. Both the aluminium layer 1116 and also the copper layer 102 can be manufactured by the 3D printing. Because aluminium may be difficult to solder, it may be of advantage, if conducting layers, such as the copper layers 102, are printed directly on the aluminium. The copper layer 102 can have different shapes, such as a rectangular shape for forming a battery terminal, or also a round shape for forming a pin for electronic components. Furthermore, the copper layer 102 can cover the aluminium layer 1116 completely, in order to possibly provide large-area electrically conducting contacts.

In the following and with reference to FIG. 13, the component carrier 100 may have three aluminium layers 1116 and copper layers 102 applied thereon is illustrated in a side view. It can be seen that two of the three aluminium layers 1116 may not be covered completely by the copper layer 102, whereas one may be completely covered by the copper layer 102.

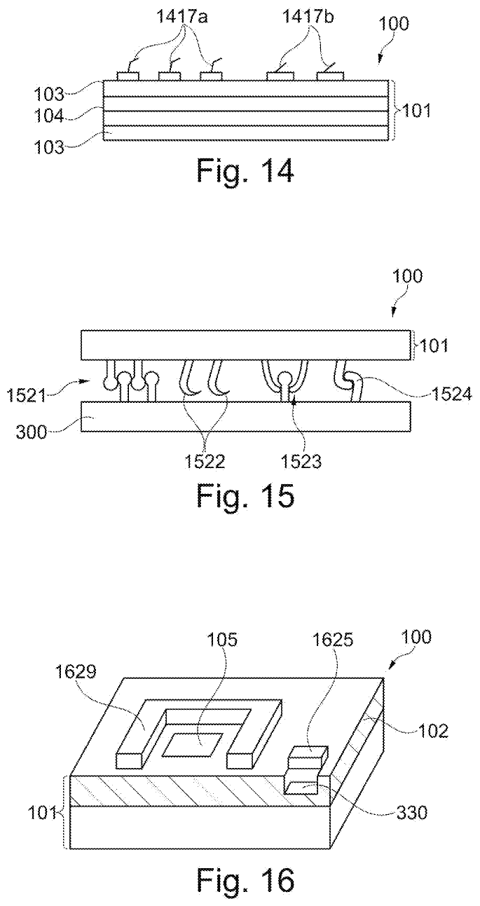

In the following and with reference to FIG. 14, the three-dimensionally printed structure may be formed at least partially as an electrically conducting connection element, in particular a spring contact. The spring contact can be printed directly on the carrier body 101. In FIG. 14, two different springs 1417a, 1417b are illustrated, which may differ in their shape. The springs 1417a, 1417b may serve as flexible electrical contacts, such that movements at the contacts 1417a, 1417b and/or at the component carrier 101 can be intercepted, and the spring contacts 1417a, 1417b may not be impaired in their signal transmission by the movement. Furthermore, the three-dimensionally printed structure can be formed as a damping element, in particular as a spring 1417a, 1417b, wherein the damping element 1417a, 1417b may not be electrically conducting, but may serve only as an element for receiving mechanical vibrations.

In the following and with reference to FIG. 15, the three-dimensionally printed structure is illustrated as a mechanical connection element 1521, 1522, 1523, 1524, which may be formed in particular as a snap connection 1523, a hook and loop connection 1522, a slide fastener connection 1521, a guide rail and/or a guide pin 1524. The mechanical connection element 1521, 1522, 1523, 1524 may be configured to form a releasable connection. All the connection elements 1521, 1522, 1523, 1524 mentioned above can be configured to provide electrically conducting connections. The hook and loop connection 1522 can for example be used to attach the carrier body 101 to corresponding hook and loop connections on textile elements. By the snap connection 1523 (or also a clamping connection), the component carrier 100 can be fixed from a side to a further component carrier 300. The mechanical connection elements 1521, 1522, 1523, 1524 can be used to connect the component carrier 100 to a further component carrier 300, such that possibly at least mechanical and/or electrical connections can be established between two different component carriers 100, 300. The mechanical connection elements 1521, 1522, 1523, 1524 can further be used to connect the component carrier 100 to another device, to possibly fix it to a module, to possibly connect it to an electronic component, or to possibly introduce this in a housing and to possibly fix it releasably.

In the following and with reference to FIG. 16, the three-dimensionally printed structure is illustrated as a reinforcement structure 1625, in particular a reinforcement structure of the electrically conducting layer structures and/or of the electrically isolating layer structures. Or it is illustrated as a heat-conducting structure 1629. A component 105, which may be surrounded by the heat-conducting structure 1629, may be arranged on the carrier body 101. The heat-conducting structure 1629 may surround the component 105 at at least one side. It may also be possible that the heat-conducting structure 1629 may surround the component 105 completely. By the heat-conducting structure 1629, heat, which may be generated by the component 105, may be dissipated, such that the component 105 may be prevented from an overheating and thus from damages. The heat-dissipating structure 1629 can be printed directly on the carrier body 101 or also in the carrier body 101. Also, the copper layer 102 can serve as a heat-dissipating structure, on which copper layer 102 components can be applied (printed) thereon. The heat-dissipating structure 1629 can have different shapes. In FIG. 16, the heat-dissipating structure 1629 may have a rectangular shape, an oval or round shape may also be possible. Furthermore, the carrier body 101 may have a recess 330. A three-dimensionally printed reinforcement 1625 may be deposited at at least one side of the recess 330 on the surface of the carrier body. The reinforcement 1625 may increase the stability of the recess 330. The reinforcement 1625 can also be arranged around the component 105, in order to thus possibly protect the component 105 from impacts on at least one side. The reinforcement 1625 in FIG. 16 may have a rectangular shape, other shapes (round, oval, trapezoid-shape) may also be applicable.

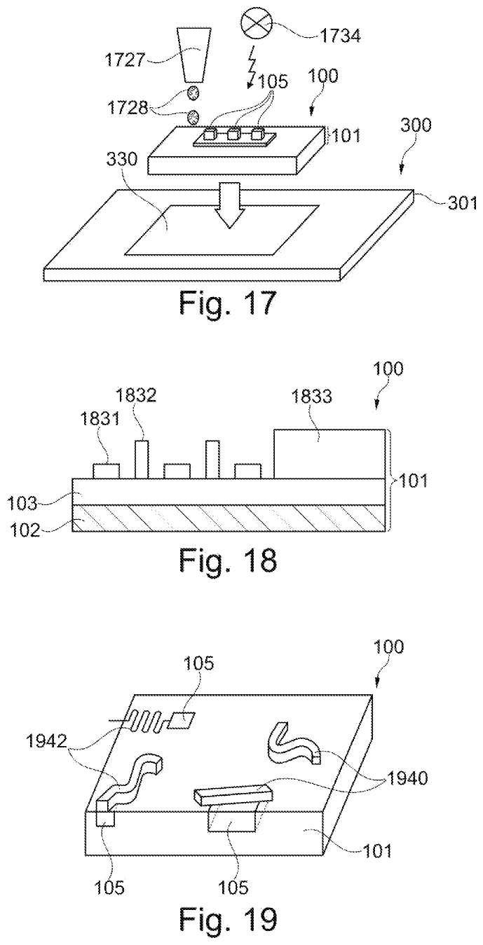

In the following and with reference to FIG. 17, a method for manufacturing a component carrier 100 is illustrated, wherein at least a part of the component carrier 100 may be formed as a three-dimensionally printed structure. A further component carrier 300 is illustrated, wherein the further component carrier 300 can be produced by the same manufacturing method. The component carrier 100 may be printed directly on and/or in the further component carrier 300. The further component carrier 300 may provide a carrier body 301 with a surface, on/in which the component carrier 100 may be formed by 3D printing. The further component carrier 300 may have a recess 330, in which the component carrier 100 can be printed. A processing device such as a printing head 1727 (which can also be a material supply jet nozzle) may have a printable material 1728. The printable material 1728 may be output by the printing head 1727, such that it can possibly form a three-dimensionally printed structure of the component carrier 100. Thus, the component carrier 100 may be printed three-dimensionally on and/or in the further component carrier 300, thereby using the printable material 1728. Furthermore, a treatment device 1734, such as a laser device, can be provided, which may emit a laser beam for treating the printable material 1728. The printable material 1728, such as, e.g., a powdery material, can thereby be melted or sintered, in order to possibly form a solidified three-dimensionally printed structure. It may also be possible that the printing head 1727 may function as an extruder, such that the melted printable material 1728 may be output at a desired position, wherein the printable material 1728 can harden by itself.

In the following and with reference to FIG. 18, the three-dimensionally printed structure 1831, 1832, 1833 is illustrated in different variations. On the one hand, the three-dimensionally printed structure 1831 may be formed as a terminal pad (or also solder pad). On the other hand, the three-dimensionally printed structure 1832 may be formed as a pin. Furthermore, the three-dimensionally printed structure 1833 may be formed as a conducting and/or non-conducting reinforcement structure. The three-dimensionally printed structure may have at least one material component, which may be selected from copper, aluminium, steel, titanium, metal alloy, plastic material and a photoresist. The terminal pads 1831 and/or pins 1832 may preferably be printed from copper. The reinforcement structure 1833 can be formed of steel or titanium, in order to possibly reinforce regions of the flexible component carrier 100. The three-dimensionally printed structure can also form the electrically isolating layer structure 103, such that the component carrier 100 can be produced almost completely with all elements by a 3D printing method. Furthermore, the three-dimensionally printed structure 1833 can be printed photoresist, which may enclose components (not shown), which are to be protected during an etching method. The three-dimensionally printed structure may further also form the copper layer 102 which can function as the electrically conducting layer and/or as the heat-dissipating layer.

In the following and with reference to FIG. 19, the three-dimensionally printed structure is illustrated as an antenna structure 1942. The antenna structure 1942 may be formed such that the antenna structure 1942 may be printable directly on and/or in the carrier body 101. Herein, the antenna structure can be printed on the carrier body 101 with different thicknesses, as a function of a desired receiving and/or transmission strength of the antenna structure 1942. The antenna structure 1942 may be coupled to a component 105, such that the component 105 can serve as a transmitter and/or receiver of antenna signals. Furthermore, the component 105 can be formed as a sensor for measuring frequencies. In this instance, the antenna structure 1942 may be coupled with components 105, which may be arranged on and/or in the carrier body 101. Furthermore, the three-dimensionally printed structure may be formed as a reinforcement structure, in particular as a glass fibre 1940. The glass fibres 1940 may serve to establish stiff regions on a flexible carrier body 101. The glass fibres 1940 can be arranged both directly on (i.e., over) components 105 and also directly on the carrier body 101, in order to possibly stiffen electrically conductingly and/or possibly electrically isolatingly layer structures at least partially.

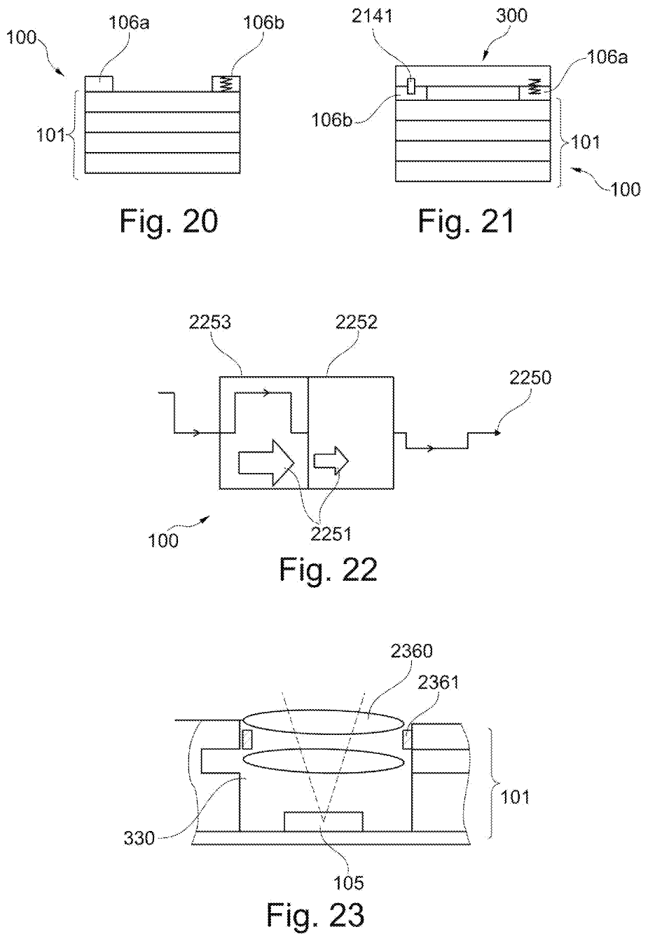

In the following and with reference to FIG. 20, a three-dimensionally printed structure is illustrated as a mechanical connection element, in particular as a threaded bush 106. The threaded bush 106b can be provided with a thread or can be used without a thread 106a. The mechanical connection element 106a, 106b may be printed directly on at least one of the plurality of layer structures of the carrier body 101.

In the following and with reference to FIG. 21, the three-dimensionally printed structure is illustrated as a mechanical connection element 106a, 106b, in particular as a threaded bush 106, wherein the mechanical connection element 106a, 106b may connect the component carrier 100 with a further component carrier 300 by a fixing means 2141. The mechanical connection element 106a, 106b can connect the component carrier 100 also to other devices or to a housing. Screws, or also bolts, can be used as fixing means 2141.

In the following and with reference to FIG. 22, a further three-dimensional structure 2253 may be formed as a further part of the component carrier, wherein the three-dimensional structure 2252 and the further three-dimensional structure 2253 may consist of different materials. In particular, the three-dimensional structure 2252 and the further three-dimensional structure 2253 may consist of materials having different heat conductivity and/or current conductivity. Furthermore, the three-dimensionally printed structure 2252 may have a higher heat conductivity and/or current conductivity than the further three-dimensional structure 2253. The different heat conductivity of the three-dimensionally printed structures 2252, 2253 is indicated in FIG. 22 with arrows 2251. The current conductivity is represented by an electrical signal 2250 running through the three-dimensionally printed structures 2252, 2253. Both the heat 2251 and also the strength of the electrical signal 2250 may be different in the corresponding three-dimensionally printed structures 2252, 2253. Furthermore, the three-dimensionally printed structure and/or the further three-dimensionally printed structure can be formed of electrically conducting materials, in particular aluminium and copper. Aluminium may have a heat conductivity smaller than the heat conductivity of copper, such that a three-dimensionally printed structure of aluminium/copper may be a good heat conductor but [may electrically conduct] worse than only copper, and likewise also a good electrical conductor. If the three-dimensionally printed structure 2252 and the further three-dimensionally printed structure 2253 are formed over each other, they may form a bi-metal element.

In the following and with reference to FIG. 23, the three-dimensionally printed structure may be formed as at least one element, which may be selected from an optical element, a light detector, a light emitter, a lens 2360, and a micro-lens. A recess 330 may be generated in the carrier body 101, within which recess the three-dimensionally printed lens 2360 may be arranged. The lens 2360 may be arranged above a component 105, wherein the component 105 may be arranged within a recess 330, preferably at the bottom. The component 105 can be a light emitter or a light detector, which may emit or detect corresponding light waves through the lens 2360. Furthermore, the lens 2360 can have at least one piezo crystal 2361, which may serve for focusing the lens 2360.

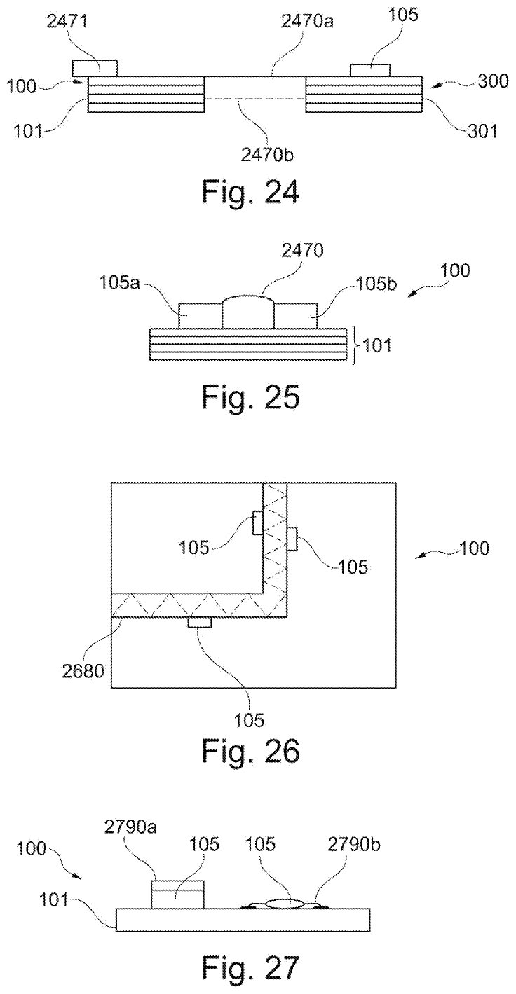

In the following and with reference to FIG. 24, the three-dimensionally printed structure is illustrated as an electrical contact 2471, in particular as an USB contact and/or a QFN contact. The electrical contact 2471 can be arranged at a side of the component carrier 100, such that e.g., a contact to the electrical contact (USB contact) 2471 can be established easily by a USB stick. Furthermore, the three-dimensionally printed structure can form the component 105, which component 105 may be in particular an active or a passive construction element (or component). Furthermore, the three-dimensionally printed structure may be formed as a breaking cut-out 2470. The breaking cut-out may connect for example two different component carriers 100 and 300 with each other and can separate them as needed. The breaking cut-out 2470a can be attached at a surface of the component carrier 100, 300. Furthermore, the breaking cut-out 2470b can also be formed on at least one of the plurality of layer structures of the respective component carriers 100, 300. The breaking cut-out 2470 can be an electrically conducting layer structure of the component carrier 100, 300, such that an electrically conducting connection can possibly be established.

Furthermore, the three-dimensionally printed structure can be formed as a rigid and/or a flexible structure, such that the breaking cut-out 2470 may be either rigid and thus may be too easy to break, or the breaking cut-out 2470 may have a certain flexibility and may break only at a particular load.

In the following and with reference to FIG. 25, a component carrier 100 is illustrated, wherein the three-dimensionally printed structure may be a breaking cut-out 2470. The breaking cut-out 2470 may connect two components 105a and 105b on one and the same component carrier 100. The breaking cut-out can function as an electrical conductor, which, as a safety function, may break for example at a too high voltage or at a too high current.

In the following and with reference to FIG. 26, the three-dimensionally printed structure is illustrated as a waveguide 2680. The waveguide 2680 can be printed directly on and/or in the component carrier 100. At least one component 105 may be arranged at the waveguide 2680, in a preferred manner, a plurality of components 105 may be arranged. The components 105 may serve as sensors (detectors) in order to possibly detect or also to possibly monitor, for example, the course or the intensity of the light waves within the guide.

In the following and with reference to FIG. 27, a component carrier is illustrated, wherein the three-dimensionally printed structure may form at least a part 2790a, 2790b of a respective component 105. The three-dimensionally printed structure can be printed directly on the component, and thus may form a part of the component 2790a. The three-dimensionally printed structure can serve for heat dissipation, e.g., as a heat sink having fins. Furthermore, the three-dimensionally printed structure can be formed as a part of a component 2790b, which may connect the component 105 with the carrier body 101, in order to thus possibly form electrically conducting structures for signal transmission. Furthermore, the three-dimensionally printed structure can also form the component 105 completely.

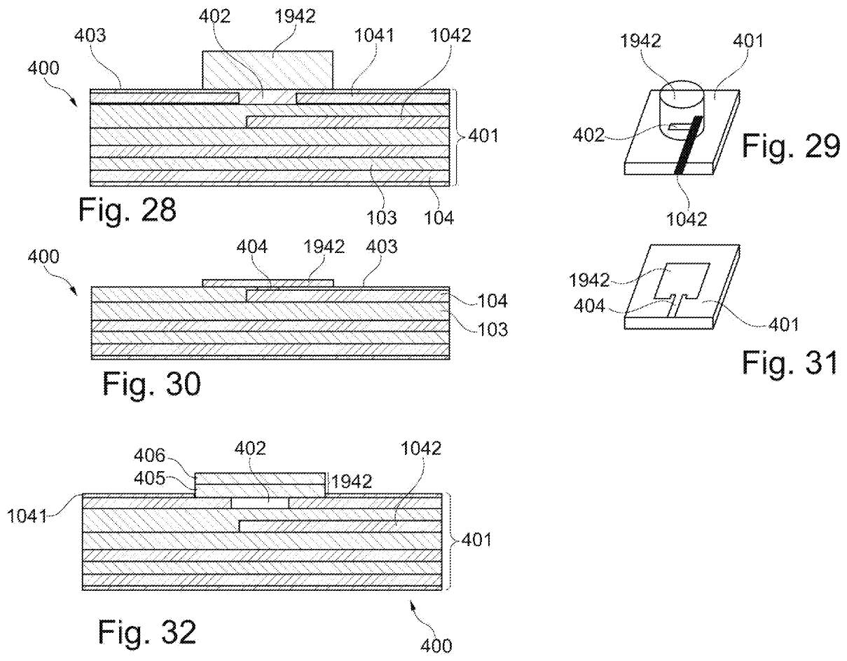

FIGS. 28 to 44 show embodiments of component carriers 400 comprising a carrier body 401 having a plurality of electrically conductive layer structures 104 and/or electrically isolating layer structures 103, wherein each component carrier 400 comprise a three-dimensionally printed structure forming at least a part of an antenna 1942 on the carrier body 401. The antenna 1942 can completely or partly be formed by the three-dimensionally printed structure. The antenna 1942 can comprise the three-dimensionally printed structure, or the three-dimensionally printed structure can comprise the antenna 1942. The features, which are described in the respective embodiments of FIGS. 28 to 44, can be combined. The antenna 1942 can be formed of copper, silver, ceramics or plastics. In case of a dielectric resonance antenna (DRA), the antenna 1942 can be made of a polymer or ABS.

FIG. 28 and FIG. 29 show a schematic cross-sectional view and a schematic perspective view of a component carrier 400, wherein the antenna 1942 is a dielectric resonant antenna (DRA) formed as a three-dimensionally printed structure of a material having a dielectric constant in a range between 5 and 20, in particular between 8 and 12. Such relative high values of the Dk are needed so that the material can act as antenna. The inventors found out that a value of Dk around 10 allows relevant electromagnetic modes to be excited. The material of the dielectric resonant antenna 1942 can be a polymer. The dielectric resonant antenna 1942 can have a cylindrical shape. The dielectric resonant antenna 1942 can be placed on a solder mask 403 which is arranged on top of an upper electrically conductive layer structure 1041. This upper electrically conductive layer structure 1041 comprises an opening or feeding slot 402 to allow information flow to a feeding line which is formed by a subjacent lower electrically conductive layer structure 1042. The feeding slot 402 can be made of an insulating material such as a solder mask material, a resin, a polymer or air.

FIG. 30 and FIG. 31 show a schematic cross-sectional view and a schematic perspective view of a component carrier 400, wherein the antenna 1942 is a patch antenna formed as a three-dimensionally printed structure of a material having a dielectric constant in a range between 2 and 6, in particular between 2 and 4. The inventors found out that an optimal radiation efficiency can be achieved within this range, and the electromagnetic field is not concentrated within the carrier body 401. The material of the patch antenna 1942 can be made of copper. The patch antenna 1942 can be placed on a solder mask 403 which is arranged on top of an upper electrically conductive layer structure 104. The patch antenna 1942 can have a rectangular shape in a plan view. Also, an electric connection 404 to the patch antenna 1942 can be printed as well. A coating can be arranged on the patch antenna 1942 to prevent oxidation.

The antenna 1942 can be formed of two different materials which are different in terms of their dielectric constants Dk, wherein the different materials are comprised either in a single material layer or separately in different layers or areas. Thereby, the bandwidth of the antenna can be increased.

An embodiment is shown in FIG. 28, wherein the different materials of the antenna 1942 are comprised in a single material layer, i.e., the feeding slot 402 is made of a material which is different from a material of the surrounding upper electrically conductive layer structure 1041.

FIG. 32 shows a schematic cross-sectional view of a component carrier 400, where the different materials of the antenna 1942 are comprised separately in different layers or areas, i.e., in layers 405 and areas 406. In this exemplary embodiment, the antenna 1942 is formed as a dielectric resonant antenna (DRA) which is directly printed as a three-dimensionally printed structure on an upper electrically conductive layer structure 1041 made of copper. A feeding slot 402 is arranged within the upper electrically conductive layer structure 1041. The feeding slot 402 can be an air cavity.

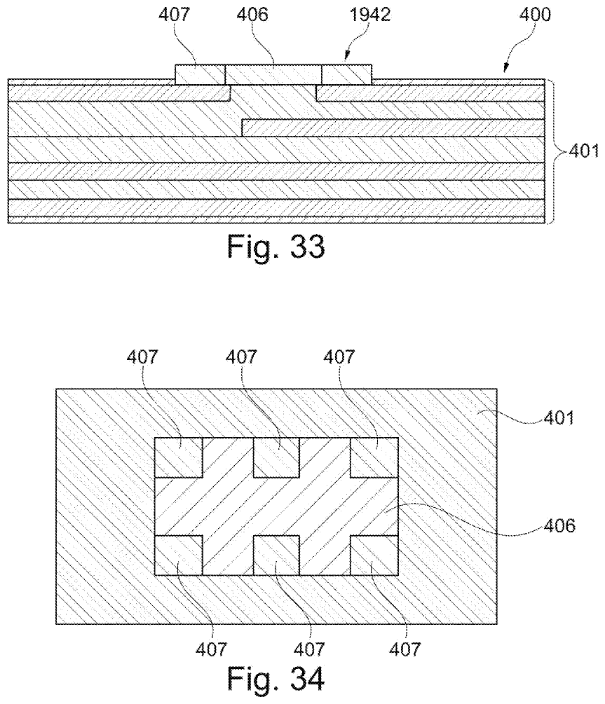

FIG. 33 and FIG. 34 show a schematic cross-sectional view and a schematic plan view of a component carrier 400, respectively, wherein the antenna 1942 is a three-dimensionally printed structure and comprises, in a cross section or in a plan view, different areas having different dielectric constants Dk. Thereby, the bandwidth can be increased so that a simple geometric shape with complex physical properties can be obtained. In the embodiment of FIG. 33, the antenna 1942 comprises, in a cross section, different areas 406, 407 having different dielectric constants Dk. In the embodiment of FIG. 34, the antenna 1942 comprises, in a plan view, different areas 406, 407 having different dielectric constants Dk.

FIG. 35 shows a schematic cross-sectional view of a component carrier 400, wherein the antenna 1942 comprises a core 411 which is made of a resin or plastics and coated or over-molded by a metal 412. The metal can be or contain silver, preferably exposed silver salt. At least one of the core 411 and the metal 412 can be a three-dimensionally printed structure.

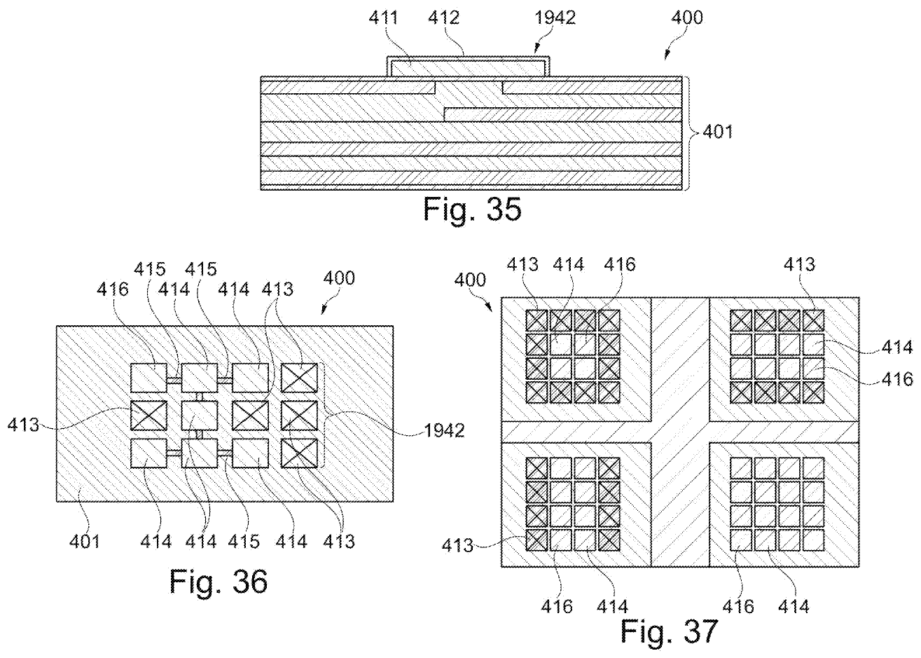

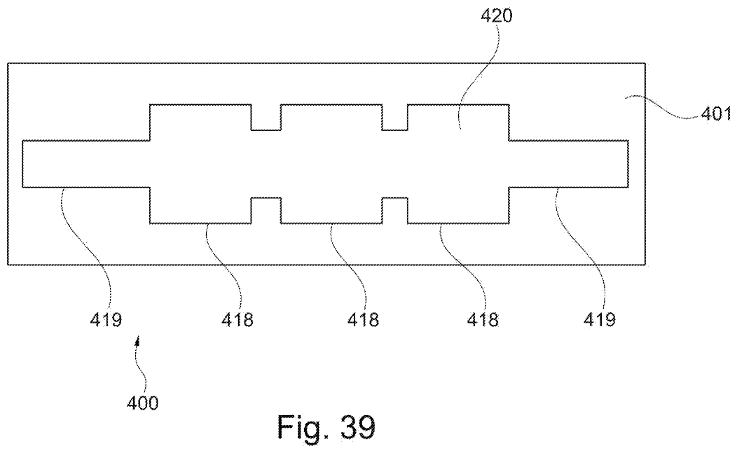

FIG. 36 and FIG. 37 show schematic plan views of a component carrier 400, wherein the antenna 1942 comprises a two-dimensional or three-dimensional matrix of an active antenna element 416 and switchable antenna elements 414. The matrix of the active antenna element 416 and the switchable antenna elements 414 can be copper pads of an upper electrically conductive layer structure 1041. The pads can be pre-manufactured in a predetermined grid pattern. The active antenna elements 416 and the switchable antenna elements 414 can be formed by conventional patterning processes such as plating, deposition, sputtering, PVD, electroless plating, for example. Alternatively, the active antenna element 416 and the switchable antenna elements 414 can also be three-dimensionally printed structures. The active antenna element 416 and the switchable antenna element 414 are connected to each other by three-dimensionally printed connection structures 415. In manufacturing the component carrier 400, the switchable antenna elements 414 can arbitrarily be switched on or off by the three-dimensionally printed connection structures 415 in order to achieve a certain reconfigurable antenna behavior in terms of frequency, bandwidth, and directivity. As shown in FIGS. 36 and 37, the two-dimensional or three-dimensional matrix further comprises unconnected elements 413. The unconnected elements 413 can likewise be pre-manufactured copper pads of the upper electrically conductive layer structure 1041, and they can belong to the predetermined grid pattern. The unconnected elements 413 are not connected to the active antenna elements 416 and the switchable antenna elements 414 by means of the three-dimensionally printed connection structures 415.

In FIG. 37, four different antennas 1942 are shown which can have a loop-shape, a bar-shape, a patch-shape, a shape of parallel bars, or a combination thereof. The different antennas 1942 in FIG. 37 can also be connected to each other, for example by diodes, switches, mems, etc. The manufacture of such component carrier 400 enables a simple design because the active antenna element 416 and the switchable antenna element 414 can have the same material and/or geometry, while specific spots for the dedicated antenna application are activated by three-dimensionally printing the three-dimensionally printed connection structures 415. Thereby, full reconfigurable antennas 1942 with a dedicated active antenna array can readily be obtained.

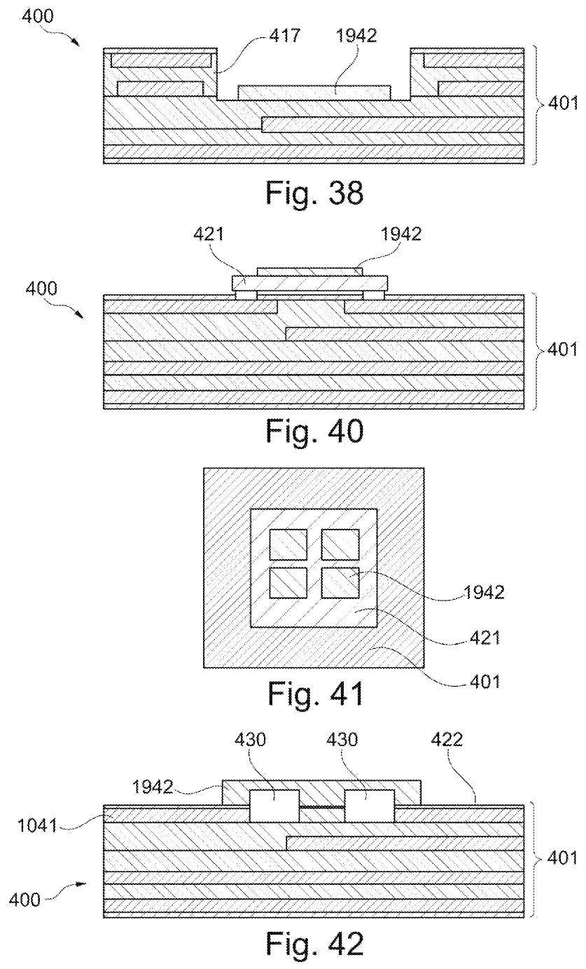

FIG. 38 shows a schematic cross-sectional view of a component carrier 400, wherein the antenna 1942 is formed as a three-dimensionally printed structure in a cavity 417 of the carrier body 401.

FIG. 39 shows a schematic plan view of a component carrier 400, wherein the three-dimensionally printed structure comprises a filter structure 420, which forms a part of an antenna. The filter structure 420 comprises resonators 418 which are connected by waveguides 419. The entire filter structure 420 can be arranged within a cavity 417 of the carrier body 401. Thereby, different structures such as waveguide and resonating structures 419, 418 can be integrated in the filter structure 420. The cavity can be metallized before placing the filter structure 420 therein. The filter structure 420 can be a dielectric structure which is placed on predetermined locations in the cavity of the carrier body 401 and works as a filter for a signal. The cavity can be further filled by air, or partially or completely filled with the dielectric material.

FIG. 40 and FIG. 41 show a schematic cross-sectional view and a schematic plan view of a component carrier 400, respectively, wherein the antenna 1942 is directly formed as a three-dimensionally printed structure on a semiconductor chip 421. As shown in FIG. 41, the antenna 1942 can be similar to those of FIGS. 36 and 37. The semiconductor chip 421 can be a communication chip for a chip-to-chip communication.

FIG. 42 shows a schematic cross-sectional view of a component carrier 400, wherein the antenna 1942 is a three-dimensionally printed structure and comprises a hollow structure, in particular to achieve a weight reduction. The hollow structure comprises at least one cavity 430. The antenna 1942 can be arranged on a solder mask 422 which is arranged on an upper electrically conductive layer structure 1041.

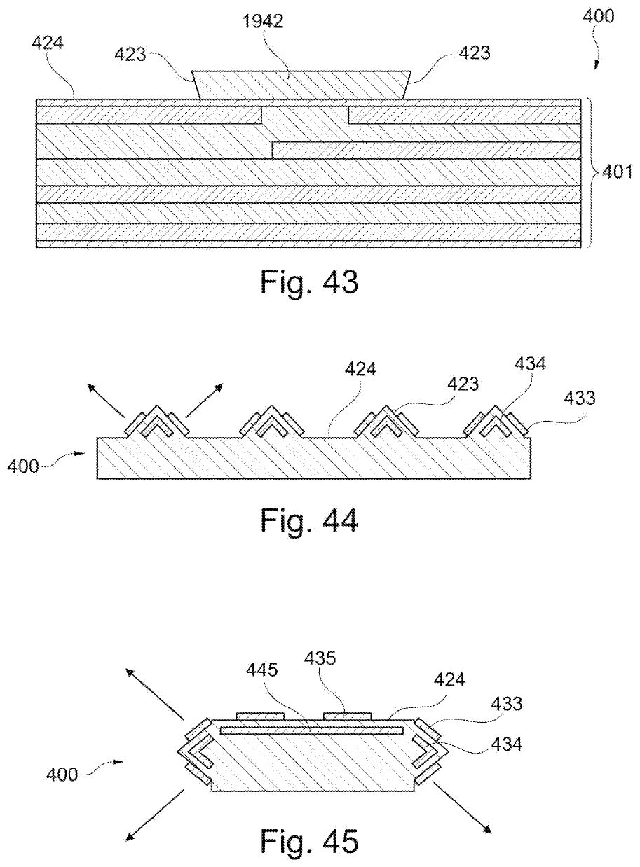

FIG. 43 shows a schematic cross-sectional view of a component carrier 400, wherein the antenna 1942 is a three-dimensionally printed structure and comprises outer sidewalls 423 which are tapered with respect to a main surface 424 of the component carrier 400 by an angle which is smaller than 90 deg., in particular smaller than 80 deg. Thereby, the antenna 1942 is able to emit in a larger angle. In the embodiment of FIG. 43, the sidewalls 423 form a kind of undercut. In another embodiment, the sidewalls 423 may have a conical shape, i.e., a reverse shape as compared with the undercut.

FIG. 44 and FIG. 45 show schematic cross-sectional views of a component carrier 400. The antenna 1942 is a three-dimensionally printed structure and comprises outer sidewalls 423 which are tapered with respect to a main surface 424 of the component carrier 400 by an angle which is smaller than 90 deg., in particular smaller than 80 deg. The outer sidewalls 423 may have a conical shape as shown in the embodiment in FIG. 44, or they may reversely form an undercut as in the embodiment of FIG. 43. The antenna 1942 further comprises inner layers 434 which are substantially arranged in parallel to the outer sidewalls 423 and made of the same material as the outer sidewalls 423. The inner layers 434 and outer layers 433 can be made of copper. A dielectric material can be arranged between the inner layers 434 and outer layers 433. In FIG. 44, the inner layers 434 and outer layers 433 are arranged along the main surface 424. In FIG. 45, the inner layers 434 and outer layers 433 are arranged on a side face, preferably on both side faces, of the component carrier 400, wherein the side faces extend perpendicularly to the main surface 424 of the component carrier 400. In addition, the antenna 1942 comprises layers 435, 445 which are arranged in parallel to the main surface 424. A dielectric material can be arranged between the layers 435, 445.

Supplementarily, it is to be noted that “comprising” (or “having”) does not exclude other elements or steps, and that “a” or “an” does not exclude a plurality. Furthermore, it is noted that features or steps, which are described with reference to one of the embodiment examples described above, can also be used in combination with other features or steps of other embodiment examples described above.

List of reference numerals:

| | | | |
|---|---|---|---|
| 100, 300 | component carrier | 423 | sidewall |
| 101, 301, | carrier body | 424 | main surface |
| 401 | | | |
| 102 | copper layer | 433 | outer layer |
| 103 | electrically isolating layer | 434 | inner layer |
| 104 | electrically conducting layer | 435 | layer |
| 105 | component | 445 | layer |
| 106 | connection element | 511 | solder depot |
| 207 | encapsulation | 612 | sliding contact |
| 330 | recess | 713 | material A |
| 400 | component carrier | 714 | material B |
| 402 | feeding slot | 715 | material C |
| 403 | solder mask | | |
| 404 | electric connection | | |
| 405 | layers | | |
| 406 | areas | | |
| 407 | areas | | |
| 408 | pins | | |
| 409 | contacts | | |
| 410 | terminal pads | | |
| 411 | core | | |
| 412 | metal | | |
| 413 | unconnected element | | |
| 414 | switchable antenna element | | |
| 415 | 3D printed connection | | |
| | structure | | |
| 416 | active antenna element | | |
| 417, 430 | cavity | | |
| 418 | resonators | | |
| 419 | waveguides | | |
| 420 | filter structure | | |
| 421 | semiconductor chip | | |
| 422 | solder mask | | |
| 1041 | upper electrically conductive | | |
| | layer structure | | |
| 1042 | lower electrically conductive | | |
| | layer structure | | |
| 1116 | aluminium layer | | |
| 1417 | damping element | | |
| 1521 | slide fastener elements | | |
| 1522 | hook and loop elements | | |
| 1523 | clamping elements | | |
| 1524 | anchor elements | | |
| 1625 | reinforcement | | |
| 1626 | recess | | |
| 1629 | heat-conducting structure | | |
| 1727 | printing head | | |
| 1728 | printable material | | |
| 1734 | treatment device | | |
| 1831, 1832, | three-dimensionally printed | | |
| 1833 | structure | | |
| 1940 | glass fibre | | |
| 1942 | antenna structure | | |
| 2141 | fixing element | | |
| 2250 | electrical signal | | |
| 2251 | arrows (heat) | | |
| 2252 | three-dimensionally printed | | |
| | structure | | |
| 2253 | further three-dimensionally | | |
| | printed structure | | |
| 2360 | lens | | |
| 2361 | piezo crystal | | |
| 2470 | bridge | | |
| 2471 | electrical contact | | |
| 2680 | waveguide | | |
| 2790 | part of a component | | |
| R | stacking direction | | |

1. A component carrier, comprising:
a carrier body having a plurality of electrically conductive layer structures and/or electrically isolating layer structures; and
a three-dimensionally printed structure forming at least a part of an antenna on the carrier body.

2. The component carrier according to claim 1, wherein the antenna is one of:
a dielectric resonant antenna formed of dielectric material; and
a patch antenna formed of conductive material.

3. The component carrier according to claim 2, wherein
the material of the dielectric resonant antenna has a dielectric constant in a range between 5 and 20, in particular between 8 and 12; and
the patch antenna has a dielectric constant in a range between 2 and 6, in particular between 2 and 4.

4. The component carrier according to claim 1, wherein
the antenna is formed of two different materials which are different in terms of their dielectric constants, wherein the different materials are comprised either in a single material layer or separately in different layers or areas.

5. The component carrier according to claim 1, wherein
the antenna comprises, in a cross section or in a plan view, different areas having different dielectric constants.

6. The component carrier according to claim 1, wherein
the antenna is formed of copper, silver, ceramics or plastics.

7. The component carrier according to claim 1, wherein
the antenna comprises a core which is coated or over-molded, wherein a coating or over-molding material is different to the material of the core.

8. The component carrier according to claim 1, wherein
the antenna comprises a two-dimensional or three-dimensional matrix of at least one active antenna element and at least one switchable antenna element, wherein the three-dimensionally printed structure is a three-dimensionally printed connection structure which connects the at least one active antenna element with the at least one switchable antenna element.

9. The component carrier according to claim 1, wherein
the antenna is formed in a cavity.

10. The component carrier according to claim 1, wherein
the three-dimensionally printed structure comprises a filter structure, a waveguide structure, or a resonating structure, or a combination thereof.

11. The component carrier according to claim 1, wherein
the antenna is directly formed on a semiconductor chip.

12. The component carrier according to claim 1, wherein
the antenna comprises a hollow structure.

13. The component carrier according to claim 1, wherein
the antenna comprises sidewalls which are tapered with respect to a main surface of the component carrier by an angle which is smaller than 90 degrees, in particular smaller than 80 degrees.

14. The component carrier according to claim 1, wherein the three-dimensionally printed structure is formed according any one of the following embodiments:
the three-dimensionally printed structure is formed in the interior and/or at a surface of the carrier body;
the three-dimensionally printed structure is formed along a stacking direction of the plurality of layer structures,
the three-dimensionally printed structure is formed perpendicular to a stacking direction of the plurality of layer structures;
the three-dimensionally printed structure has different cross-sectional areas in a stacking direction of the plurality of layer structures and/or perpendicular to a stacking direction of the plurality of layer structures;
the three-dimensionally printed structure forms at least partially the electrically conductive layer structures and/or the electrically isolating layer structures;
the three-dimensionally printed structure is formed as a rigid and/or flexible structure;
the three-dimensionally printed structure is a heat conducting structure;
the three-dimensionally printed structure has at least one material component, which is selected from copper, aluminum, steel, titanium, metal alloy, plastic material, and photoresist;
the three-dimensionally printed structure is formed as a reinforcement structure of the electrically conductive layer structures and/or of the electrically isolating layer structures;
the three-dimensionally printed structure forms a surface of the carrier body, wherein areas of the surface differ in respect of their hardness, roughness and/or elasticity.

15. The component carrier according to claim 1, wherein the component carrier is formed according any one of the following embodiments:
the carrier body has a recess, wherein the three-dimensionally printed structure is printed within the recess;
at least a part of the carrier body is encapsulated by the three-dimensionally printed structure as an encapsulation, wherein the encapsulation comprises at least one of steel, titanium, silver, aluminum or gold;
the component carrier further has:
an electronic component, surface-mounted at and/or embedded in at least one of the plurality of the electrically conductive layer structures and/or of the electrically isolating layer structures;
the three-dimensionally printed structure is formed such that a further three-dimensionally printed structure is printable thereon;
a further part of the component carrier is formed as a further three-dimensionally printed structure, wherein the three-dimensionally printed structure and the further three-dimensionally printed structure consist of different materials;
at least one of the plurality of electrically conductive layer structures has at least one of copper, aluminum, nickel, silver, gold, palladium and wolfram, wherein one of the mentioned materials is optionally coated with graphene;
at least one of the plurality of electrically isolating layer structures has at least one of the of resin, reinforced or non-reinforced resin, epoxy resin, bismaleimide-triazine resin, FR-4, FR-5, cyanate ester, polyphenylene derivatives, glass, prepreg material, polyimide, polyamide, liquid crystalline polymer, epoxy-based composition film, polytetrafluoroethylene, a ceramic, and a metal oxide;
the component carrier is formed as a board;
the component carrier is configured as one of a conductor board and a substrate;
the component carrier is configured as a lamination-type component carrier.

16. A method for manufacturing a component carrier, the method comprising:
connecting a plurality of electrically conductive layer structures and/or electrically isolating layer structures for forming a carrier body; and
forming an antenna at least partially as a three-dimensionally printed structure on the carrier body by three-dimensional printing.

17. The method according to claim 16, wherein
the antenna comprises a two-dimensional or three-dimensional matrix of at least one active antenna element and at least one switchable antenna element, the method comprises:
connecting the at least one active antenna element to the at least one switchable antenna element by three-dimensionally printing the three-dimensionally printed structure as a three-dimensionally printed connection structure.

18. The method according to claim 16, wherein
the step of three-dimensional printing comprises at least one of selective laser melting, selective laser sintering, aerosol jet printing, electron beam melting, and inkjet-printing.

19. The method according to claim 16, comprising:
forming a cavity having a complementary shape to the antenna; and
filling the cavity by the three-dimensionally printed structure to form the antenna.

20. A method of designing a component carrier, the component carrier having a carrier body with a plurality of electrically conductive layer structures and/or electrically isolating layer structures and a three-dimensionally printed structure forming at least a part of an antenna on the carrier body, the method comprising:
determining at least one parameter, which used in a step of three-dimensional printing the three-dimensionally printed structure, so as to obtain a predetermined resonant frequency of the antenna, wherein the parameter is at least one of a height, an area, and a volume of the antenna.

21. The method according to claim 20, wherein
the antenna comprises a two-dimensional or three-dimensional matrix of at least one active antenna element and at least one switchable antenna element;
wherein the three-dimensionally printed structure is designed to connect the at least one active antenna element to the at least one switchable antenna element by three-dimensionally printing the three-dimensionally printed structure as a three-dimensionally printed connection structure.
